(19) United States
(12) Patent Application Publication
(10) Pub. No.: US 2024/0224682 A1
(43) Pub. Date: Jul. 4, 2024

(54) DISPLAY DEVICE AND METHOD FOR MANUFACTURING DISPLAY DEVICE

(71) Applicant: SHARP KABUSHIKI KAISHA, Sakai City, Osaka (JP)

(72) Inventors: YOSHIHIRO UETA, Sakai City, Osaka (JP); TAZUKO KITAZAWA, Sakai City, Osaka (JP)

(21) Appl. No.: 17/769,582

(22) PCT Filed: Nov. 6, 2019
(86) PCT No.: PCT/JP2019/043513

§ 371 Date: Jan. 18, 2024

(51) Int. Cl. H10K 59/32; H10K 59/122; H10K 59/35; H10K 59/80; H10K 71/60; H10K 102/00

(52) U.S. Cl. CPC H10K 59/32; H10K 59/122; H10K 59/352; H10K 59/80515; H10K 59/80524; H10K 71/60; H10K 2102/321

(57) ABSTRACT

A display device includes a blue light-emitting layer, a red light-emitting layer disposed so as to overlap the blue light-emitting layer, and a green light-emitting layer disposed so as to overlap the blue light-emitting layer. A light-emitting area of the blue light-emitting layer is greater than a light-emitting area of the red light-emitting layer, and the light-emitting area of the red light-emitting layer is greater than a light-emitting area of the green light-emitting layer.

### TECHNICAL FIELD

The disclosure relates to a display device including light-emitting layers of a plurality of colors, and a method for manufacturing a display device.

### BACKGROUND ART

A full-color display requires pixels that emit light in three primary colors of red (R), green (G), and blue (B), and a structure in which light-emitting layers that emit light in the three primary colors are disposed in a plane is considered as an arrangement of the light-emitting layers. Since the structure in which the light-emitting layers are disposed in a plane requires an area three times as large as an area of one pixel (each light-emitting layer), there is room for improvement in definition and miniaturization of the display.

Thus, a structure in which the light-emitting layers of R, G, and B are layered in a vertical direction is considered (PTL 1). In this structure, anode and cathode of the three primary colors, positive and negative carrier injection layers of the three primary colors, and insulating layers of the three primary colors are layered. At least one of the anode and cathode is drawn through an opening that opens in all layers located in an upper layer of the corresponding light-emitting layer.

### CITATION LIST

### Patent Literature

PTL 1: WO 96/19792 (published Jun. 27, 1996)

### SUMMARY

### Technical Problem

In the structure in PTL 1 described above, since the light-emitting layers of R, G, and B are layered in the vertical direction, a display device can be reduced in area. However, a luminous efficiency of the light-emitting layers of R, G, and B, and a luminosity factor of light of R, G, and B emitted from the light-emitting layers of R, G, and B are not considered for an area of the light-emitting layers of R, G, and B. Thus, there is a problem that a variation occurs in brightness of R, G, and B displayed on the display device.

An object of an aspect of the disclosure is to provide a display device and a method for manufacturing a display device, capable of improving balance of brightness of R, G, and B displayed on the display device.

### Solution to Problem

A display device according to the disclosure includes: a blue light-emitting layer configured to emit blue light; a red light-emitting layer configured to overlap the blue light-emitting layer in a plan view and emit red light; and a green light-emitting layer configured to overlap the blue light-emitting layer in the plan view and emit green light, wherein a light-emitting area of the blue light-emitting layer is greater than a light-emitting area of the red light-emitting layer, and the light-emitting area of the red light-emitting layer is greater than a light-emitting area of the green light-emitting layer.

A method for manufacturing a display device according to the disclosure includes: forming, on a substrate, a first electrode to be electrically connected to a red light-emitting layer; forming, on the substrate, a second electrode to be electrically connected to a green light-emitting layer; forming the red light-emitting layer on the first electrode; forming the green light-emitting layer on the second electrode; forming a common electrode on the red light-emitting layer and the green light-emitting layer; forming a blue light-emitting layer on the common electrode; and forming, on the blue light-emitting layer, a third electrode to be electrically connected to the blue light-emitting layer, wherein a light-emitting area of the blue light-emitting layer is greater than a light-emitting area of the red light-emitting layer, and the light-emitting area of the red light-emitting layer is greater than a light-emitting area of the green light-emitting layer.

Another method for manufacturing a display device according to the disclosure includes: forming, on a substrate, a first electrode to be electrically connected to a red light-emitting layer; forming, on the substrate, a second electrode to be electrically connected to a green light-emitting layer; forming the red light-emitting layer on the first electrode; forming the green light-emitting layer on the second electrode; forming, on the red light-emitting layer and the green light-emitting layer, a first common electrode portion common to the red light-emitting layer and the green light-emitting layer; forming, on the first common electrode portion, a third electrode to be electrically connected to a blue light-emitting layer; forming the blue light-emitting layer on the third electrode; and forming a second common electrode portion to be electrically connected to the blue light-emitting layer, wherein a light-emitting area of the blue light-emitting layer is greater than a light-emitting area of the red light-emitting layer, and the light-emitting area of the red light-emitting layer is greater than a light-emitting area of the green light-emitting layer.

A still another method for manufacturing a display device according to the disclosure includes: forming, on a substrate, a first electrode to be electrically connected to a red light-emitting layer; forming the red light-emitting layer on the first electrode; forming a third common electrode portion on the red light-emitting layer; forming, on the third common electrode portion, a second electrode to be electrically connected to a green light-emitting layer; forming the green light-emitting layer on the second electrode; forming a fourth common electrode portion on the green light-emitting layer; forming, on the fourth common electrode portion, a third electrode to be electrically connected to a blue light-emitting layer; forming the blue light-emitting layer on the third electrode; and forming a fifth common electrode portion on the blue light-emitting layer, wherein a light-emitting area of the blue light-emitting layer is greater than a light-emitting area of the red light-emitting layer, and the light-emitting area of the red light-emitting layer is greater than a light-emitting area of the green light-emitting layer.

### Advantageous Effects of Disclosure

An aspect of the disclosure can improve balance of brightness of R, G, and B displayed on a display device.

### BRIEF DESCRIPTION OF DRAWINGS

FIG. 1 is a cross-sectional view of a display device according to a first embodiment.

FIG. 2 is a plan view of the display device.

FIG. 3(a) is a plan view of a modified example of a second electrode provided on the display device, and FIG. 3(b) is a cross-sectional view of the modified example.

FIGS. 4(a) to (d) are cross-sectional views illustrating a manufacturing method for the display device.

FIGS. 5(a) to (d) are cross-sectional views illustrating the manufacturing method for the display device.

FIGS. 6(a) to (c) are cross-sectional views illustrating the manufacturing method for the display device.

FIGS. 7(a) to (c) are cross-sectional views illustrating the manufacturing method for the display device.

FIGS. 8(a) and (b) are cross-sectional views illustrating the manufacturing method for the display device.

FIGS. 9(a) and (b) are cross-sectional views illustrating the manufacturing method for the display device.

FIGS. 10(a) and (b) are cross-sectional views illustrating the manufacturing method for the display device.

FIG. 11 is a cross-sectional view of a display device according to a second embodiment.

FIG. 12 is a cross-sectional view of a display device according to a third embodiment.

### DESCRIPTION OF EMBODIMENTS

### First Embodiment

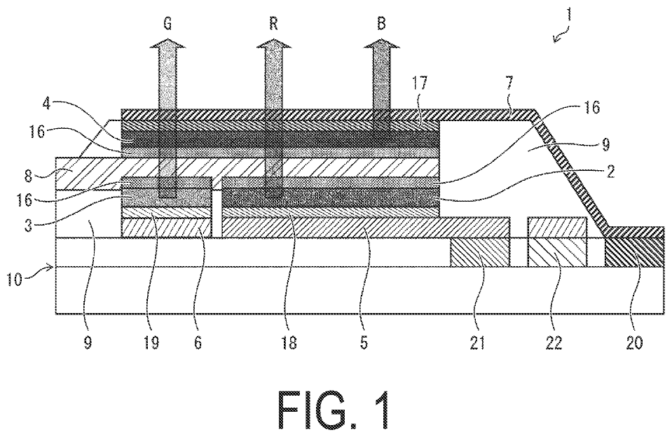

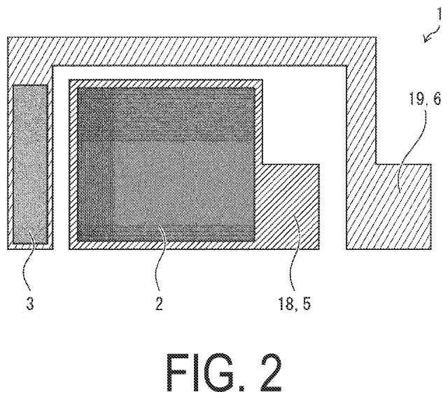

FIG. 1 is a cross-sectional view of a display device 1 according to a first embodiment. FIG. 2 is a plan view of the display device 1. The display device 1 includes a blue light-emitting layer 4 that emits blue light, a red light-emitting layer 2 that is disposed so as to overlap the blue light-emitting layer 4 in a plan view and emits red light, and a green light-emitting layer 3 that is disposed so as to overlap the blue light-emitting layer 4 in the plan view and emits green light. A light-emitting area of the blue light-emitting layer 4 is greater than a light-emitting area of the red light-emitting layer 2, and the light-emitting area of the red light-emitting layer 2 is greater than a light-emitting area of the green light-emitting layer 3. In this way, the light-emitting area of the green light-emitting layer 3 is smaller than the light-emitting area of the blue light-emitting layer 4, and is smaller than the light-emitting area of the red light-emitting layer 2.

In the present specification, the “light-emitting area” means an area of a region of a light-emitting layer from which light is emitted. A pixel covers an edge of an anode or a cathode, an edge cover having an opening exposing the anode or the cathode is provided, and the anode, the light-emitting layer, and the cathode are formed so as to overlap each other in the opening in the region from which light is emitted. The light-emitting area can be determined by, for example, causing light emission from the light-emitting layer and measuring an area of the region from which light is emitted. Further, the light-emitting area described above can also be determined by measuring an area of the region in which the anode, the light-emitting layer, and the cathode overlap each other in the opening. An area of the opening of the edge cover is typically the light-emitting area.

The display device 1 includes a substrate 10. A first thin film transistor (TFT) 21 for controlling light emission of the red light-emitting layer 2, a second thin film transistor 22 for controlling light emission of the green light-emitting layer 3, and a third thin film transistor 20 for controlling light emission of the blue light-emitting layer 4 are formed on the substrate 10. A first electrode 5 corresponding to the red light-emitting layer 2 is formed on the substrate 10 so as to be electrically connected to the first thin film transistor 21, and a second electrode 6 corresponding to the green light-emitting layer 3 is formed on the substrate 10 so as to be electrically connected to the second thin film transistor 22.

The first electrode 5 and the first thin film transistor 21 may be electrically connected to each other via a lead wiring line (not illustrated). The same also applies to the second electrode 6 and the second thin film transistor 22, and a third electrode 7 and the third thin film transistor 20. A first electron transport layer (ETL) 18 is formed between the first electrode 5 and the red light-emitting layer 2. Then, a second electron transport layer 19 is formed between the second electrode 6 and the green light-emitting layer 3. A partition 9 that insulates the red light-emitting layer 2, the first electron transport layer 18, and the first electrode 5 from the green light-emitting layer 3, the second electron transport layer 19, and the second electrode 6 is formed on the substrate 10. It is preferable that the partition 9 does not have transparency from a perspective of suppressing stray light to an adjacent pixel.

The first electrode 5 and the second electrode 6 function as a cathode, and also function as a reflector when the first electrode 5 and the second electrode 6 are formed of a metal such as aluminum.

A ratio of the light-emitting area of the red light-emitting layer 2, the light-emitting area of the green light-emitting layer 3, and the light-emitting area of the blue light-emitting layer 4 is preferably determined according to a ratio of a luminous efficiency of the red light-emitting layer 2 and a luminosity factor of light from the red light-emitting layer 2, a luminous efficiency of the green light-emitting layer 3 and a luminosity factor of light from the green light-emitting layer 3, and a luminous efficiency of the blue light-emitting layer 4 and a luminosity factor of light from the blue light-emitting layer 4. In this way, the light of the red light-emitting layer 2, the light of the green light-emitting layer 3, and the light of the blue light-emitting layer 4 that are emitted at the same current are equal in luminance. Here, the term “equal” includes a term “substantially equal”, and also includes, for example, an error and a fluctuation of approximately ±10% of the luminance of each color of RGB to a degree that white color reproduction when each color of RGB is simultaneously emitted is not affected.

Note that the luminance is the amount acquired by differentiating, by a light-emitting area, a luminous intensity in which a radiation intensity of light radiated from a light-emitting element is weighted by a luminosity factor for each wavelength. The luminosity factor is a standard relative luminosity factor (standard spectral luminous efficiency) with respect to a maximum luminosity factor of a person defined in General Conference of Weights and Measures, and indicates a degree of a sense of brightness of each wavelength by normalizing, to 1, light having a wavelength (555 nm) most strongly sensed by an eye of a person. The luminance can be measured by, for example, a commercial luminance meter.

The ratio is preferably determined according to a ratio of an inverse of a multiplication value of the luminous efficiency of the red light-emitting layer 2 and the luminosity factor of the light from the red light-emitting layer 2, an inverse of a multiplication value of the luminous efficiency of the green light-emitting layer 3 and the luminosity factor of the light from the green light-emitting layer 3, and an inverse of a multiplication value of the luminous efficiency of the blue light-emitting layer 4 and the luminosity factor of the light from the blue light-emitting layer 4. In this way, the light of the red light-emitting layer 2, the light of the green light-emitting layer 3, and the light of the blue light-emitting layer 4 that are emitted at the same current are equal in luminance, and a drive circuit and a color reproduction algorithm can be simplified.

The light-emitting area of the green light-emitting layer 3 is preferably less than one-tenth of the light-emitting area of the blue light-emitting layer 4. In this way, the light of the green light-emitting layer 3 and the light of the blue light-emitting layer 4 that are emitted at the same current are equal in luminance.

It is preferable that, in the plan view, the entire red light-emitting layer 2 and a part of the blue light-emitting layer 4 are disposed so as to overlap each other, and the entire green light-emitting layer 3 and a part of the blue light-emitting layer 4 are disposed so as to overlap each other. In this way, the red light-emitting layer 2 and the blue light-emitting layer 4 are layered, and the green light-emitting layer 3 and the blue light-emitting layer 4 are layered, and thus red light emission, green light emission, and blue light emission can be achieved in a projection area of the blue light-emitting layer 4.

The red light-emitting layer 2 and the green light-emitting layer 3 are preferably disposed so as not to overlap each other in the plan view. In this way, two layers of the red light-emitting layer 2 and the green light-emitting layer 3, and the blue light-emitting layer 4 are substantially layered, and thus the display device 1 can be thinner than a configuration in which three layers of the red light-emitting layer 2, the green light-emitting layer 3, and the blue light-emitting layer 4 are layered.

A common electrode 8 having first polarity and being electrically connected to all of the red light-emitting layer 2, the green light-emitting layer 3, and the blue light-emitting layer 4 is formed so as to be sandwiched between the blue light-emitting layer 4, and the red light-emitting layer 2 and the green light-emitting layer 3. The first polarity is polarity as an anode (anode) or polarity as a cathode (cathode). In the present embodiment, the first polarity has the polarity as the anode, and the common electrode 8 is transparent and has the polarity as the anode.

A common hole transport layer (HTL) 16 is formed between the common electrode 8 and the blue light-emitting layer 4, and between the common electrode 8, and the red light-emitting layer 2 and the green light-emitting layer 3.

The first electrode 5 has second polarity opposite to the first polarity, and is electrically connected to the red light-emitting layer 2. The second electrode 6 has the second polarity, and is electrically connected to the green light-emitting layer 3. Note that, when the first polarity is the polarity of the anode, the second polarity is the polarity of the cathode, and when the first polarity is the polarity of the cathode, the second polarity is the polarity of the anode. In the present embodiment, the second polarity is the polarity of the cathode.

Note that, in the present embodiment, an example in which the common electrode 8 is the anode, and the first electrode 5 and the second electrode 6 are the cathode has been described, but the disclosure is not limited thereto. Conversely, even when the common electrode 8 is the cathode, and the first electrode 5 and the second electrode 6 are the anode, an effect of the present embodiment can be obtained. Note that, when the common electrode 8 is the anode, and the first electrode 5 and the second electrode 6 are the cathode, the common electrode 8 and the common hole transport layer 16 can be made common, and thus a manufacturing procedure becomes simplified.

A third electron transport layer 17 is formed on the blue light-emitting layer 4. The third electrode 7 having the second polarity and being electrically connected to the blue light-emitting layer 4 via the third electron transport layer 17 is formed on the third electron transport layer 17 and formed so as to be electrically connected to the third thin film transistor 20.

The third electrode 7 functions as the cathode. The common hole transport layer 16, the third electron transport layer 17, and the third electrode 7 are transparent.

In this way, each of the first electrode 5 and the second electrode 6 is provided on an opposite side to the common electrode 8 with respect to the red light-emitting layer 2 and the green light-emitting layer 3, and the third electrode 7 is provided on an opposite side to the common electrode 8 with respect to the blue light-emitting layer 4. Then, the first electrode 5 and the second electrode 6 are formed of the same material and formed in the same layer. In other words, the first electrode 5 and the second electrode 6 are formed by performing patterning after one or more layers of a conductive film (including aluminum, silver, transparent conductive film, or the like) are formed as a film. The first electrode 5 and the second electrode 6 can be formed of, for example, a metal such as aluminum.

As illustrated in FIG. 1, it is preferable that the red light-emitting layer 2 and the green light-emitting layer 3 that emit light having a longer wavelength are disposed on the substrate 10 side, and the blue light-emitting layer 4 that emits light having a shorter wavelength is disposed on a surface side of the display device 1. Conversely, in a case of a configuration in which the blue light-emitting layer 4 is disposed on the substrate 10 side, and the red light-emitting layer 2 and the green light-emitting layer 3 are disposed on the surface side of the display device 1, the blue light emitted from the blue light-emitting layer 4 is absorbed by the red light-emitting layer 2 and the green light-emitting layer 3, and it is difficult for the blue light to be suitably emitted from the display device 1.

In the present embodiment, a ratio among a projection area of the red light-emitting layer 2, a projection area of the green light-emitting layer 3, and the projection area of the blue light-emitting layer 4 is determined based on the luminous efficiency of the red light-emitting layer 2, the green light-emitting layer 3, and the blue light-emitting layer 4, and the luminosity factor of the red light from the red light-emitting layer 2, the green light from the green light-emitting layer 3, and the blue light from the blue light-emitting layer 4 such that the red light from the red light-emitting layer 2, the green light from the green light-emitting layer 3, and the blue light from the blue light-emitting layer 4 are equal in luminance.

The luminous efficiency includes external quantum efficiency (EQE), or photoluminescence quantum yield (PLQY).

The luminosity factor is a constant determined based on a wavelength of light. The external quantum efficiency or the photoluminescence quantum yield is a constant that mainly depends on a material of the light-emitting layer, and is a constant that can be estimated before the display device 1 is manufactured. When the luminous efficiency includes the photoluminescence quantum yield, area usage efficiency of each light-emitting layer is improved. When the luminous efficiency includes the external quantum efficiency, the luminous efficiency of each light-emitting layer is improved.

As shown in Table 1 below, the projection area of each color pixel of the red light-emitting layer 2, the green light-emitting layer 3, and the blue light-emitting layer 4 is changed in proportion to (1/(luminous efficiency (QY)×luminosity factor)). In this way, when the same current flows through a pixel of each color of the red light-emitting layer 2, the green light-emitting layer 3, and the blue light-emitting layer 4, the luminance of light emission from the red light-emitting layer 2, the green light-emitting layer 3, and the blue light-emitting layer 4 is identical to each other.

TABLE 1

| | QY | | | | |
|---|---|---|---|---|---|
| | | RELATIVE | LUMINOSITY | EML | |
| COLOR | [%] | VALUE | FACTOR | AREA | SIZE |
| B | 65 | 0.8 | 0.1 | 10.3 | 3.2 |
| G | 80 | 1.0 | 1.0 | 1.0 | 1.0 |
| R | 90 | 1.1 | 0.1 | 8.9 | 3.0 |

Table 1 shows the luminous efficiency (QY), the luminosity factor, and a pixel size of the red light-emitting layer 2, the green light-emitting layer 3, and the blue light-emitting layer 4. All numerical values shown in Table 1 are numerical values with reference to green (G). More specifically, external quantum efficiency (EQE) is used instead of quantum efficiency (QY) as the luminous efficiency. The projection area of each pixel of the red light-emitting layer 2, the green light-emitting layer 3, and the blue light-emitting layer 4 is determined so as to be in proportion to (1/(luminous efficiency×luminosity factor)).

In this way, by changing the projection area of the pixel of each color of the red light-emitting layer 2, the green light-emitting layer 3, and the blue light-emitting layer 4 based on the luminous efficiency and the luminosity factor, the luminance having the same brightness can be obtained from the red light-emitting layer 2, the green light-emitting layer 3, and the blue light-emitting layer 4 with the same current flowing through the red light-emitting layer 2, the green light-emitting layer 3, and the blue light-emitting layer 4.

Further, a drive circuit and a drive algorithm of the red light-emitting layer 2, the green light-emitting layer 3, and the blue light-emitting layer 4 can be made common to be simplified by making the red light-emitting layer 2, the green light-emitting layer 3, and the blue light-emitting layer 4 equal in current-luminance characteristics in such a manner.

Further, the red light-emitting layer 2 and the green light-emitting layer 3 can be contained within a pixel area of the blue light-emitting layer 4 by changing the projection area of the pixel of the red light-emitting layer 2, the green light-emitting layer 3, and the blue light-emitting layer 4 in such a manner. As a result, a tandem structure can be achieved by layering only two layers of the blue light-emitting layer 4, and the red light-emitting layer 2 and the green light-emitting layer 3.

The blue light-emitting layer 4, and the red light-emitting layer 2 and the green light-emitting layer 3 are symmetrically vertically disposed with respect to the common electrode 8 and the common hole transport layer 16, and thus three layers of the red light-emitting layer 2, the green light-emitting layer 3, and the blue light-emitting layer 4 can be simplified to two layers to be layered, and a manufacturing cost and man-hours of a tandem structure of an organic EL element can be reduced.

Furthermore, when the first electrode 5 and the second electrode 6 wired to the red light-emitting layer 2 and the green light-emitting layer 3 being a lower layer of the blue light-emitting layer 4 are layered in two layers, an area needed for wiring can be reduced.

As described above, a layering type light-emitting element having a small pixel size can be achieved in the number of layers smaller than that in the related art, and a high-resolution display and a compact display can be manufactured at a low cost.

In the present embodiment, the light-emitting area of each color of the red light-emitting layer 2, the green light-emitting layer 3, and the blue light-emitting layer 4 is (light-emitting area of blue light-emitting layer 4)≥((light-emitting area of red light-emitting layer 2)+(light-emitting area of green light-emitting layer 3)). Thus, the red light-emitting layer 2 and the green light-emitting layer 3 can be contained within the projection area of the blue light-emitting layer 4.

A quantum dot used in the light-emitting layer indicates a characteristic in which light having a wavelength shorter than a light emission wavelength of the quantum dot is absorbed, and a carrier optically excited in the quantum dot is recombined to emit light. The light emission is referred to as photoexcitation light emission. Due to a property of the photoexcitation light emission, the light from the blue light-emitting layer 4 is absorbed by the green light-emitting layer 3 and the red light-emitting layer 2, and photoexcitation light emission is performed in the corresponding colors. Further, the light from the green light-emitting layer 3 is absorbed by the red light-emitting layer 2, and photoexcitation light emission is performed. Such photoexcitation light emission may cause an unintended fluctuation in luminance and a hue change, which is not thus preferable.

In order to prevent the photoexcitation light emission on a light extraction surface side, the blue light-emitting layer 4 is disposed on an uppermost portion, the red light-emitting layer 2 and the green light-emitting layer 3 are disposed lower than the blue light-emitting layer 4, and the common electrode 8 serving as a common anode and the common hole transport layer 16 are disposed between the blue light-emitting layer 4, and the red light-emitting layer 2 and the green light-emitting layer 3. According to the configuration, the anode and the hole transport layer (HTL) needed for each color of the red light-emitting layer 2, the green light-emitting layer 3, and the blue light-emitting layer 4 in a known layered structure are made common to all the colors of the red light-emitting layer 2, the green light-emitting layer 3, and the blue light-emitting layer 4. Thus, a layered structure is more simplified than the known layered structure.

The first electrode 5 having reflectivity and the first electron transport layer 18 are disposed in a lower layer of the red light-emitting layer 2. The second electrode 6 having reflectivity and the second electron transport layer 19 are disposed in a lower layer of the green light-emitting layer 3.

The blue light-emitting layer 4 shares the common electrode 8 with the red light-emitting layer 2 and the green light-emitting layer 3. Then, the third electron transport layer 17 having transparency and the third electrode 7 having transparency are layered in this order above the blue light-emitting layer 4.

The partition 9 is provided in an appropriate shape between and around the layers of the red light-emitting layer 2, the green light-emitting layer 3, and the blue light-emitting layer 4 for insulating and wiring the layers of the red light-emitting layer 2, the green light-emitting layer 3, and the blue light-emitting layer 4. In a known structure, a partition serving as an insulating layer needs to be provided around each pixel for insulating the periphery of each pixel of red, green, and blue disposed on a plane. However, in the present embodiment, the red light-emitting layer 2 and the green light-emitting layer 3, and the blue light-emitting layer 4 are layered in the light-emitting area of the blue light-emitting layer 4, and thus only the periphery corresponding to one pixel in the known structure may be insulated. Thus, the amount of a material of the partition 9 needed for insulation may be reduced to approximately one-third of the known layered configuration.

Each electrode of the first electrode 5, the second electrode 6, the third electrode 7, and the common electrode 8, each electron transport layer of the third electron transport layer 17, the first electron transport layer 18, and the second electron transport layer 19, the common hole transport layer 16, and the partition 9 can be formed by using a material typically used for an organic light emitting diode (OLED) and a quantum dot light emitting diode (QLED). It is preferable that the partition 9 does not have transparency from the perspective of suppressing stray light to an adjacent pixel.

As illustrated in FIG. 2, in the plan view, the second electrode 6 does not overlap the first electrode 5, is formed so as to surround the first electrode 5 spaced from the first electrode 5, and is electrically connected to the green light-emitting layer 3 via the second electron transport layer 19.

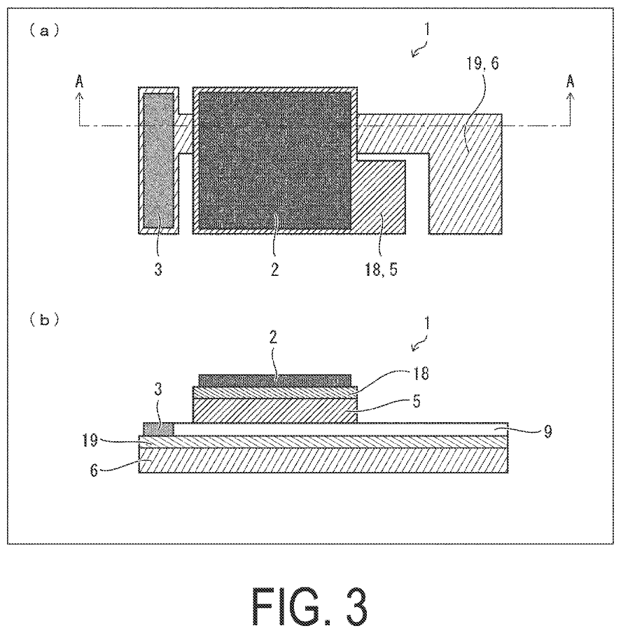

FIG. 3(a) is a plan view of a modified example of the second electrode 6 provided in the display device 1, and FIG. 3(b) is a cross-sectional view taken along a plane AA illustrated in FIG. 3(a). Constituent elements similar to the constituent elements described above are given the same reference numerals, and detailed descriptions thereof are not repeated.

In the plan view, the first electrode 5 and the second electrode 6 may be disposed so as to overlap each other. In other words, as illustrated in FIGS. 3(a) and (b), the second electrode 6 and the second electron transport layer 19 may be formed so as to be joined to the green light-emitting layer 3 through a lower side of the red light-emitting layer 2, the first electron transport layer 18, the first electrode 5, and the partition 9.

FIGS. 2 and 3 illustrate that the first electrode 5 connects the red light-emitting layer 2 being the lowest layer to the first thin film transistor 21, and the second electrode 6 connects the green light-emitting layer 3 being the lowest layer to the second thin film transistor 22. FIG. 2 illustrates an example in which the first electrode 5 being a wiring line related to the red light-emitting layer 2 and the second electrode 6 being a wiring line related to the green light-emitting layer 3 are disposed in a surface of the substrate 10. FIG. 3 illustrates an example in which the first electrode 5 being a wiring line related to the red light-emitting layer 2 is layered above the second electrode 6 being a wiring line related to the green light-emitting layer 3 via the partition 9 being an insulating layer.

Although the example illustrated in FIG. 2 needs an area acquired by simply adding an area corresponding to the wiring line of the first electrode 5 and an area corresponding to the wiring line of the second electrode 6, the layered structure can be simplified.

Although the example illustrated in FIG. 3 needs the extra partition 9 serving as the insulating layer since the second electrode 6 and the first electrode 5 are layered, a wiring line area acquired by adding an area corresponding to the wiring line of the first electrode 5 and an area corresponding to the wiring line of the second electrode 6 can be reduced by an area in which the first electrode 5 and the second electrode 6 overlap each other.

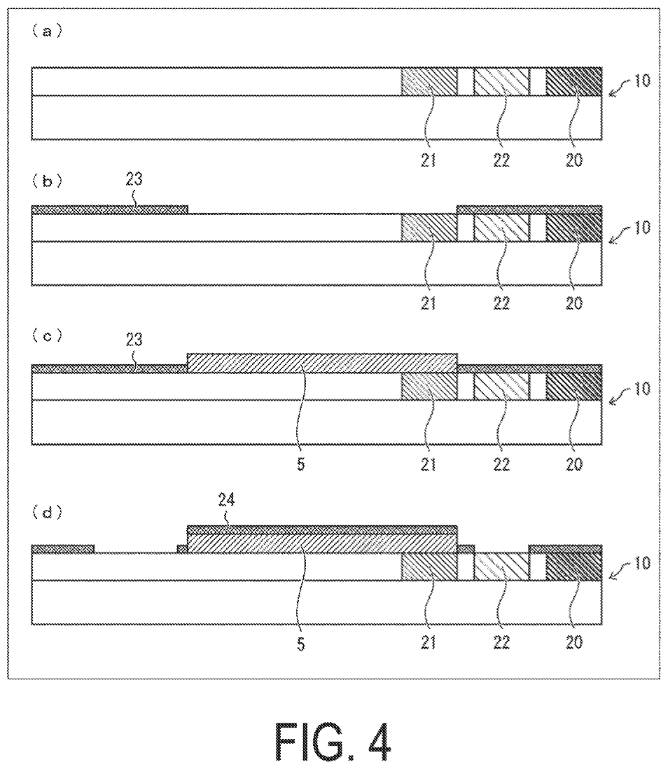

Next, an example of a manufacturing method for the display device 1 is exemplified. FIGS. 4(a) to (d) are cross-sectional views illustrating the manufacturing method for the display device 1. Constituent elements similar to the constituent elements described above are given the same reference numerals, and detailed descriptions thereof are not repeated.

A known thin film transistor preparation step, a known wiring line material, and a known mask can be used in the manufacturing method for the display device 1. In order to prepare the display device 1 according to the present embodiment, first, as illustrated in FIG. 4(b), a mask 23 for forming the first electrode 5 is formed on the leveled substrate 10 on which the first thin film transistor 21, the second thin film transistor 22, and the third thin film transistor 20 illustrated in FIG. 4(a) are formed. The mask 23 is a photomask by photolithography using a metal mask or a photoresist.

Then, as illustrated in FIG. 4(c), the first electrode 5 to become a cathode wiring line to the red light-emitting layer 2 is formed by a means such as sputtering, vapor deposition, and application. Next, the mask 23 is removed from the substrate 10, and, as illustrated in FIG. 4(d), a mask 24 for forming the second electrode 6 to become a cathode wiring line to the green light-emitting layer 3 is then formed.

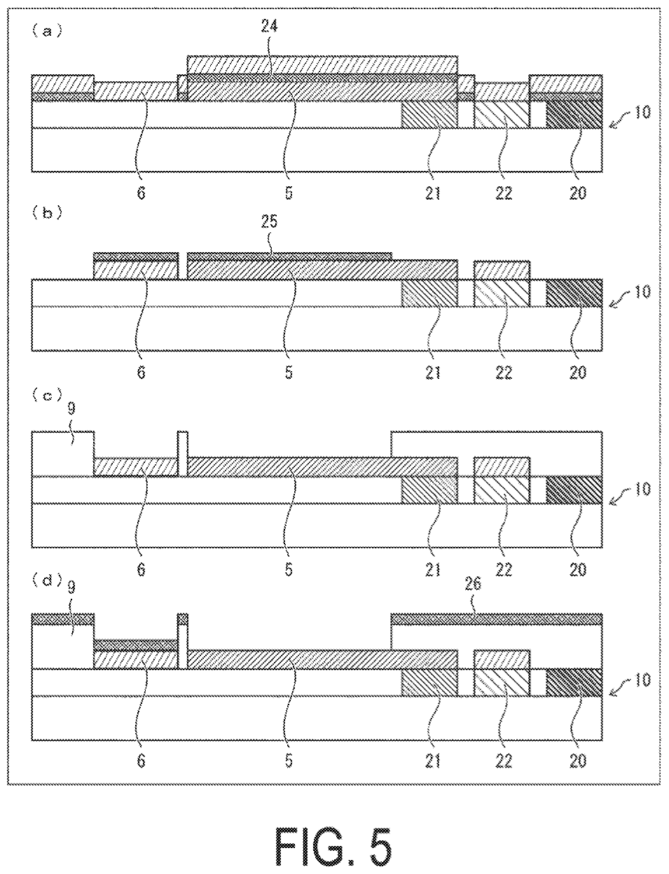

FIGS. 5(a) to (d) are cross-sectional views illustrating the manufacturing method for the display device 1. Constituent elements similar to the constituent elements described above are given the same reference numerals, and detailed descriptions thereof are not repeated.

Subsequently, as illustrated in FIG. 5(a), the second electrode 6 to become the cathode wiring line to the green light-emitting layer 3 is formed by using the mask 24 by a means similar to that above such as sputtering, vapor deposition, and application.

Then, the mask 24 is removed, and, as illustrated in FIG. 5(b), a mask 25 for forming the partition 9 is formed on the first electrode 5 and the second electrode 6. Next, as illustrated in FIG. 5(c), after the partition 9 is formed by the mask 25, the mask 25 is removed. Note that, as another means for forming the partition 9, a partition material may be applied to the entire surface of the substrate 10, and ashing or etching may be performed on an area unnecessary to form the partition 9 via the mask 25. Subsequently, as illustrated in FIG. 5(d), a mask 26 open in a region for forming the red light-emitting layer 2 is formed.

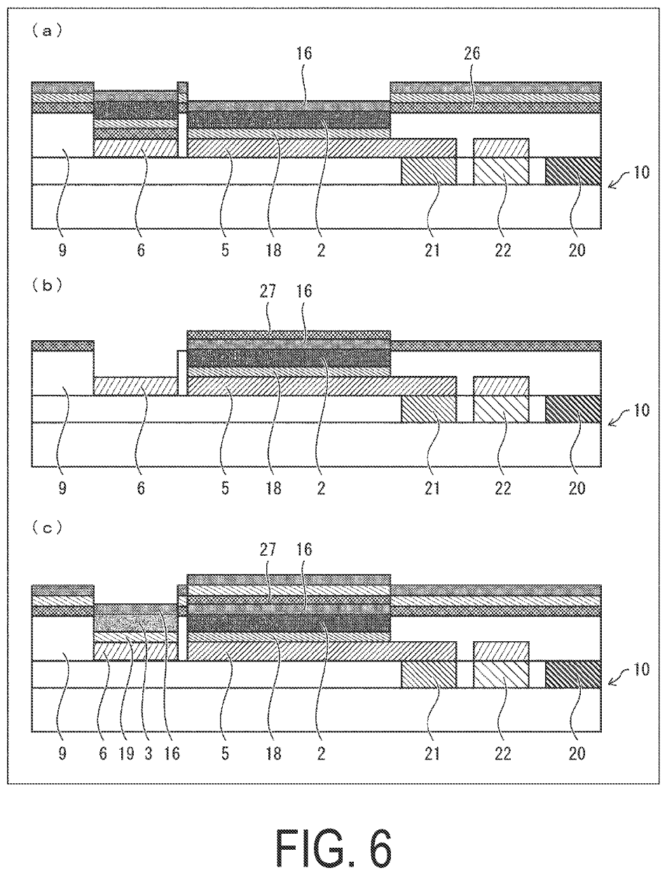

FIGS. 6(a) to (c) are cross-sectional views illustrating the manufacturing method for the display device 1. Constituent elements similar to the constituent elements described above are given the same reference numerals, and detailed descriptions thereof are not repeated.

Then, a first electron transport layer 18 is formed on the first electrode 5 by a means similar to that above such as sputtering, vapor deposition, and application. Next, while using the same mask 26, the red light-emitting layer 2 and the common hole transport layer 16 are formed on the first electron transport layer 18 so as to be layered in this order. In a case of the QLED, the red light-emitting layer 2 can be formed by using colloidal solution application, printing by ink-jet and the like, or a transfer method. In a case of the OLED, the red light-emitting layer 2 can be formed by using printing or vapor deposition. The common hole transport layer 16 is formed by a means similar to the means for forming the first electron transport layer 18.

Subsequently, as illustrated in FIG. 6(b), the mask 26 is removed and replaced with a mask 27 for the green light-emitting layer 3. Then, as illustrated in FIG. 6(c), the second electron transport layer 19, the green light-emitting layer 3, and the common hole transport layer 16 are formed on the second electrode 6 so as to be layered in this order. At this time, the common hole transport layer 16 formed on the red light-emitting layer 2 serves a function of protecting the red light-emitting layer 2 from process damage by a solvent for a photomask.

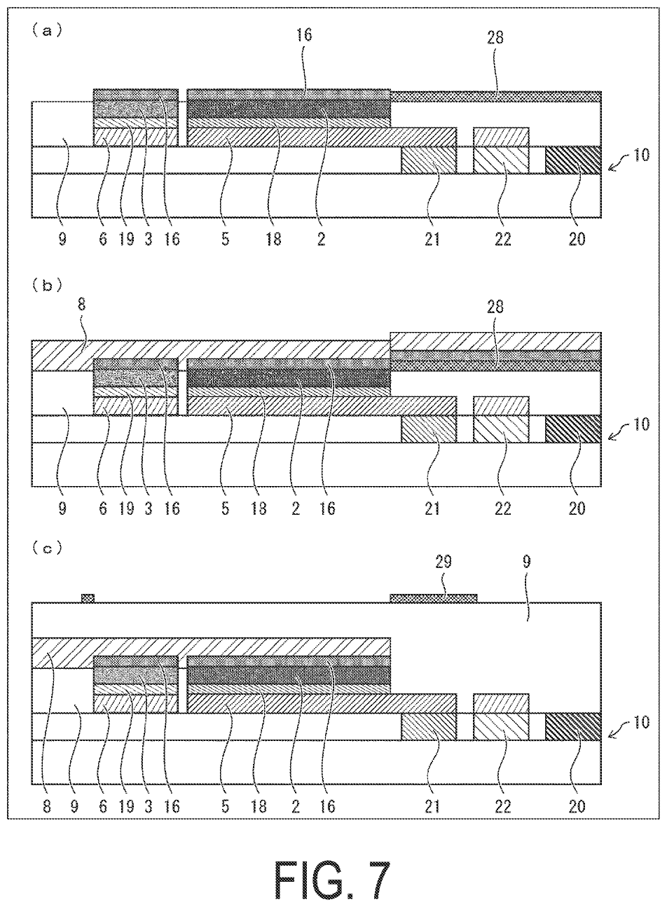

FIGS. 7(a) to (c) are cross-sectional views illustrating the manufacturing method for the display device 1. Constituent elements similar to the constituent elements described above are given the same reference numerals, and detailed descriptions thereof are not repeated.

Next, as illustrated in FIG. 7(a), the mask 27 is removed and replaced with a mask 28 for forming the common electrode 8 to become a common anode. Subsequently, the common electrode 8 is formed as illustrated in FIG. 7(b). Then, as illustrated in FIG. 7(c), the mask 28 is removed, and the entire surface of the substrate 10 is covered with the partition 9. Next, a mask 29 is formed on a surface of the partition 9.

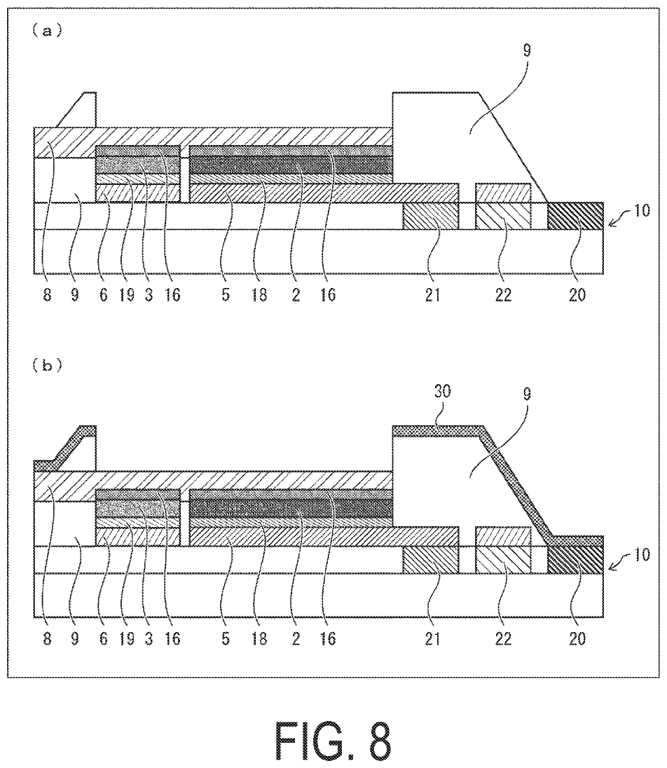

FIGS. 8(a) and (b) are cross-sectional views illustrating the manufacturing method for the display device 1. Constituent elements similar to the constituent elements described above are given the same reference numerals, and detailed descriptions thereof are not repeated.

Then, as illustrated in FIG. 8(a), after ashing or etching is performed on the surface of the partition 9, the mask 29 is removed. Next, as illustrated in FIG. 8(b), a mask 30 for the blue light-emitting layer 4 is formed.

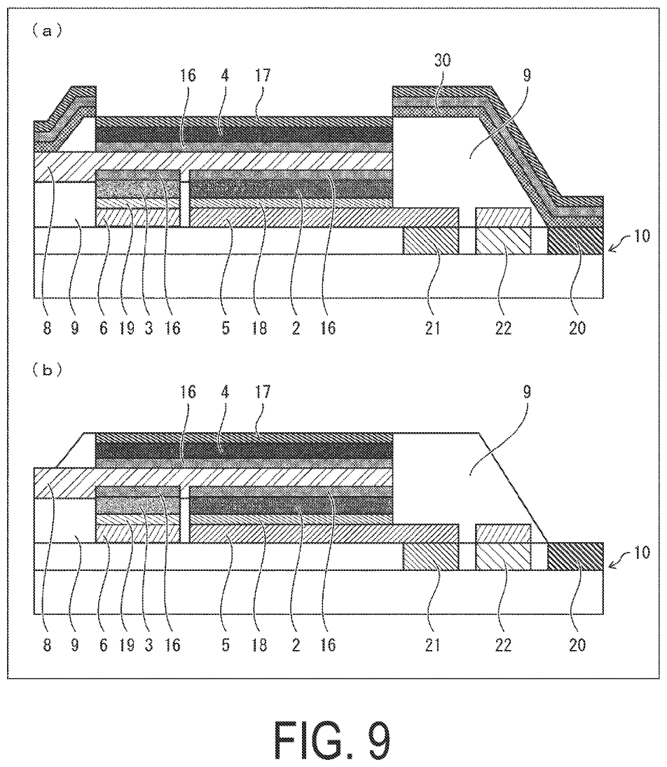

FIGS. 9(a) and (b) are cross-sectional views illustrating the manufacturing method for the display device 1. Subsequently, as illustrated in FIG. 9(a), the common hole transport layer 16, the blue light-emitting layer 4, and the third electron transport layer 17 are formed on the common electrode 8 so as to be layered in this order. Then, as illustrated in FIG. 9(b), the mask 30 is removed.

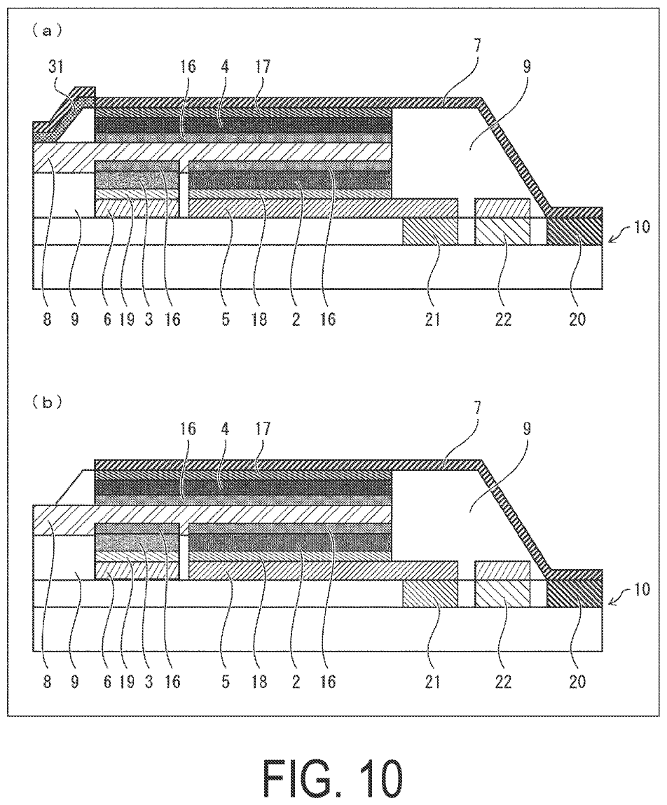

FIGS. 10(a) and (b) are cross-sectional views illustrating the manufacturing method for the display device 1. Next, as illustrated in FIG. 10(a), the third electrode 7 to become the cathode of the blue light-emitting layer 4 is formed via a mask 31. Subsequently, as illustrated in FIG. 10(b), the mask 31 is removed, and an element structure of the display device 1 is completed. Then, the common electrode 8 to become an exposed common anode and the substrate 10 are wired, the entire panel is sealed, and the display device 1 is completed.

The masks 23 to 31 described above are photomasks by photolithography using a metal mask or a photoresist. Further, the partition 9 can be formed of, for example, a resin material. Processing of the resin material is performed by using ashing or dry etching.

Note that an example in which the blue light-emitting layer 4 is layered on the red light-emitting layer 2 and the green light-emitting layer 3, and the anode is made common to the red light-emitting layer 2, the green light-emitting layer 3, and the blue light-emitting layer 4 by the common electrode 8 is described, but the disclosure is not limited thereto. Conversely, the red light-emitting layer 2 and the green light-emitting layer 3 may be layered on the blue light-emitting layer 4, and the cathode may be made common to the red light-emitting layer 2, the green light-emitting layer 3, and the blue light-emitting layer 4. In the OLED, the blue light-emitting layer 4 can be disposed on the substrate 10 side with respect to the red light-emitting layer 2 and the green light-emitting layer 3 in such a manner. The same can also apply to the QLED.

Since the common electrode 8 and the common hole transport layer 16 can be made common when the anode is made common as compared to when the cathode disposed on an electron transport layer side is made common, it is easy and preferable in terms of a simplified manufacturing procedure.

Further, an example in which the first electrode 5 and the second electrode 6 have the reflectivity is exemplified, but the first electrode 5 and the second electrode 6 may be formed to be transparent similarly to the third electrode 7, and the display device may be a transparent display type.

### Second Embodiment

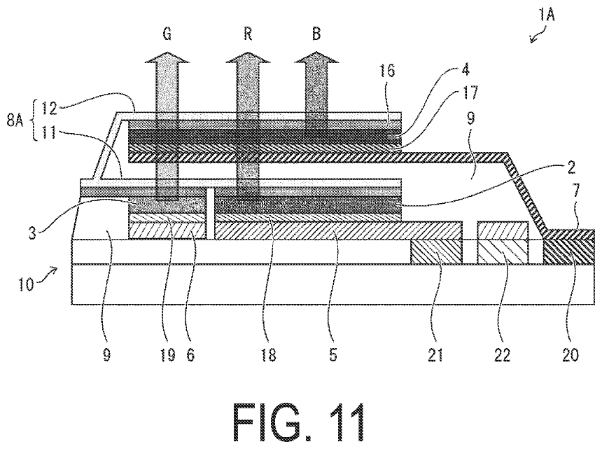

FIG. 11 is a cross-sectional view of a display device 1A according to a second embodiment. Constituent elements similar to the constituent elements described above are given the same reference numerals, and detailed descriptions thereof are not repeated.

The display device 1A has another structure in which a blue light-emitting layer 4, and a red light-emitting layer 2 and a green light-emitting layer 3 are layered, and a point different from the display device 1 according to the first embodiment is a point that the display device 1A includes a common electrode 8A. The common electrode 8A includes a first common electrode portion 11 provided between the red light-emitting layer 2 and the green light-emitting layer 3, and the blue light-emitting layer 4 in order to be electrically connected to the red light-emitting layer 2 and the green light-emitting layer 3, and a second common electrode portion 12 provided on an opposite side to the red light-emitting layer 2 and the green light-emitting layer 3 with respect to the blue light-emitting layer 4 in order to be electrically connected to the blue light-emitting layer 4.

A portion of a partition 9 between the blue light-emitting layer 4, and the red light-emitting layer 2 and the green light-emitting layer 3 has transparency. Similarly to the first embodiment, it is preferable that the portion of the partition 9 between the red light-emitting layer 2 and the green light-emitting layer 3 does not have transparency from the perspective of suppressing stray light to an adjacent pixel.

Similarly to the display device 1 according to the first embodiment, the display device 1A according to the second embodiment can also be manufactured by using a known thin film transistor preparation step, a known wiring line material, and a known mask.

The display device 1A according to the second embodiment is manufactured by a manufacturing method including: a first electrode formation step of forming, on a substrate 10, a first electrode 5 to be electrically connected to the red light-emitting layer 2; a second electrode formation step of forming, on the substrate 10, a second electrode 6 to be electrically connected to the green light-emitting layer 3; a red light-emitting layer formation step of forming the red light-emitting layer 2 on the first electrode 5; a green light-emitting layer formation step of forming the green light-emitting layer 3 on the second electrode 6; a first common electrode formation step of forming, on the red light-emitting layer 2 and the green light-emitting layer 3, the first common electrode portion 11 common to the red light-emitting layer 2 and the green light-emitting layer 3; a third electrode formation step of forming, on the first common electrode portion 11, a third electrode 7 to be electrically connected to the blue light-emitting layer 4; a blue light-emitting layer formation step of forming the blue light-emitting layer 4 on the third electrode 7; and a second common electrode formation step of forming the second common electrode portion 12 to be electrically connected to the blue light-emitting layer 4. A light-emitting area of the blue light-emitting layer 4 is greater than a light-emitting area of the red light-emitting layer 2, and the light-emitting area of the red light-emitting layer 2 is greater than a light-emitting area of the green light-emitting layer 3.

### Third Embodiment

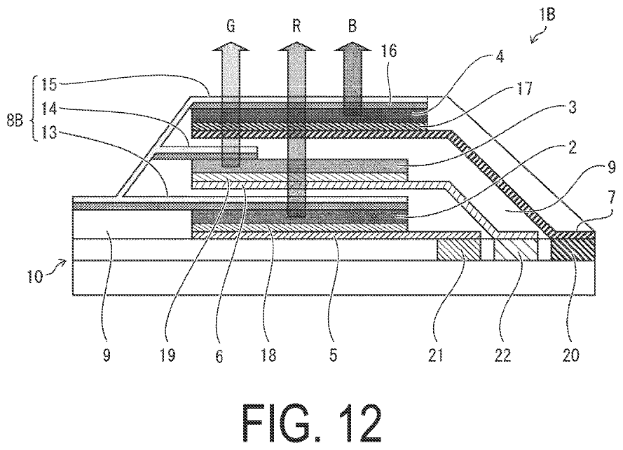

FIG. 12 is a cross-sectional view of a display device 1B according to a third embodiment. Constituent elements similar to the constituent elements described above are given the same reference numerals, and detailed descriptions thereof are not repeated.

The display device 1B has a structure in which each layer of a red light-emitting layer 2, a green light-emitting layer 3, and a blue light-emitting layer 4 is independently layered. The red light-emitting layer 2 and the green light-emitting layer 3 are disposed in different planes, and the green light-emitting layer 3 is disposed between the red light-emitting layer 2 and the blue light-emitting layer 4.

A light-emitting area of the blue light-emitting layer 4 is greater than a light-emitting area of the red light-emitting layer 2, and the light-emitting area of the red light-emitting layer 2 is greater than a light-emitting area of the green light-emitting layer 3.

As illustrated in FIG. 12, the display device 1B includes a common electrode 8B having first polarity and being electrically connected to all of the red light-emitting layer 2, the green light-emitting layer 3, and the blue light-emitting layer 4, a first electrode 5 having second polarity opposite to the first polarity and being electrically connected to the red light-emitting layer 2, a second electrode 6 having the second polarity and being electrically connected to the green light-emitting layer 3, and a third electrode 7 having the second polarity and being electrically connected to the blue light-emitting layer 4.

The first electrode 5 is provided on an opposite side to the green light-emitting layer 3 with respect to the red light-emitting layer 2, the second electrode 6 is provided on the red light-emitting layer 2 side with respect to the green light-emitting layer 3, and the third electrode 7 is provided on the green light-emitting layer 3 side with respect to the blue light-emitting layer 4.

The common electrode 8B includes a third common electrode portion 13 provided on the green light-emitting layer 3 side with respect to the red light-emitting layer 2 in order to be electrically connected to the red light-emitting layer 2, a fourth common electrode portion 14 provided on the blue light-emitting layer 4 side with respect to the green light-emitting layer 3 in order to be electrically connected to the green light-emitting layer 3, and a fifth common electrode portion 15 provided on an opposite side to the green light-emitting layer 3 with respect to the blue light-emitting layer 4 in order to be electrically connected to the blue light-emitting layer 4.

A portion of a partition 9 between the blue light-emitting layer 4 and the green light-emitting layer 3, and a portion of the partition 9 between the green light-emitting layer 3 and the red light-emitting layer 2 have transparency.

Similarly to the first and second embodiments, the structure of the third embodiment can also obtain the effect of making luminance uniform and the effect of making an anode common.

Similarly to the display device 1 according to the first embodiment, the display device 1B according to the third embodiment can also be manufactured by using a known thin film transistor preparation step, a known wiring line material, and a known mask.

The display device 1B according to the third embodiment is manufactured by a manufacturing method including: a first electrode formation step of forming, on a substrate 10, the first electrode 5 to be electrically connected to the red light-emitting layer 2; a red light-emitting layer formation step of forming the red light-emitting layer 2 on the first electrode 5; a third common electrode formation step of forming the third common electrode portion 13 on the red light-emitting layer 2; a second electrode formation step of forming, on the third common electrode portion 13, the second electrode 6 to be electrically connected to the green light-emitting layer 3; a green light-emitting layer formation step of forming the green light-emitting layer 3 on the second electrode 6; a fourth common electrode formation step of forming the fourth common electrode portion 14 on the green light-emitting layer 3; a third electrode formation step of forming, on the fourth common electrode portion 14, the third electrode 7 to be electrically connected to the blue light-emitting layer 4; a blue light-emitting layer formation step of forming the blue light-emitting layer 4 on the third electrode 7; and a fifth common electrode formation step of forming the fifth common electrode portion 15 on the blue light-emitting layer 4. The light-emitting area of the blue light-emitting layer 4 is greater than the light-emitting area of the red light-emitting layer 2, and the light-emitting area of the red light-emitting layer 2 is greater than the light-emitting area of the green light-emitting layer 3.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A display device comprising:
a blue light-emitting layer configured to emit blue light;
a red light-emitting layer configured to overlap the blue light-emitting layer in a plan view and emit red light; and
a green light-emitting layer configured to overlap the blue light-emitting layer in the plan view and emit green light,
wherein a light-emitting area of the blue light-emitting layer is greater than a light-emitting area of the red light-emitting layer, and the light-emitting area of the red light-emitting layer is greater than a light-emitting area of the green light-emitting layer; and
wherein a ratio of the light-emitting area of the red light-emitting layer, the light-emitting area of the green light-emitting layer, and the light-emitting area of the blue light-emitting layer is determined according to a luminous efficiency of the red light-emitting layer and a luminosity factor of the red light, a luminous efficiency of the green light-emitting layer and a luminosity factor of the green light, and a luminous efficiency of the blue light-emitting layer and a luminosity factor of the blue light.

2. (canceled)

3. The display device according to claim 1,
wherein the ratio is determined according to a ratio of an inverse of a multiplication value of the luminous efficiency of the red light-emitting layer and the luminosity factor of the red light, an inverse of a multiplication value of the luminous efficiency of the green light-emitting layer and the luminosity factor of the green light, and an inverse of a multiplication value of the luminous efficiency of the blue light-emitting layer and the luminosity factor of the blue light.

4. The display device according to claim 1,
wherein the light-emitting area of the green light-emitting layer is less than one-tenth of the light-emitting area of the blue light-emitting layer.

5. The display device according to claim 1,
wherein, in the plan view, the entire red light-emitting layer and the blue light-emitting layer overlap each other, and the entire green light-emitting layer and the blue light-emitting layer overlap each other.

6. The display device according to claim 1,
wherein the red light-emitting layer and the green light-emitting layer do not overlap each other in the plan view.

7. The display device according to claim 1, further comprising:
a common electrode having first polarity and being electrically connected to all of the red light-emitting layer, the green light-emitting layer, and the blue light-emitting layer;
a first electrode having second polarity opposite to the first polarity and being electrically connected to the red light-emitting layer;
a second electrode having the second polarity and being electrically connected to the green light-emitting layer; and
a third electrode having the second polarity and being electrically connected to the blue light-emitting layer,
wherein the common electrode is sandwiched between the blue light-emitting layer, and the red light-emitting layer and the green light-emitting layer,
the first electrode and the second electrode are provided on an opposite side to the common electrode with respect to the red light-emitting layer and the green light-emitting layer, respectively, and
the third electrode is provided on an opposite side to the common electrode with respect to the blue light-emitting layer.

8. The display device according to claim 7,
wherein, in the plan view, the second electrode does not overlap the first electrode.

9. The display device according to claim 7,
wherein the first electrode and the second electrode are formed of an identical material and formed in an identical layer.

10. The display device according to claim 7,
wherein, in the plan view, the first electrode and the second electrode overlap each other.

11. The display device according to claim 5, further comprising
a partition disposed between the red light-emitting layer and the green light-emitting layer and having no transparency.

12. The display device according to claim 1, further comprising:
the red light-emitting layer and the green light-emitting layer not overlapping each other in the plan view,
a common electrode having first polarity and being electrically connected to all of the red light-emitting layer, the green light-emitting layer, and the blue light-emitting layer;
a first electrode having second polarity opposite to the first polarity and being electrically connected to the red light-emitting layer;
a second electrode having the second polarity and being electrically connected to the green light-emitting layer; and
a third electrode having the second polarity and being electrically connected to the blue light-emitting layer,
wherein the first electrode and the second electrode are provided on an opposite side to the blue light-emitting layer with respect to the red light-emitting layer and the green light-emitting layer, respectively,
the third electrode is provided on the green light-emitting layer side with respect to the blue light-emitting layer,
the common electrode includes a first common electrode portion and a second common electrode portion being electrically connected to each other,
the first common electrode portion is provided between the red light-emitting layer and the green light-emitting layer, and the third electrode, and
the second common electrode portion is provided on an opposite side to the third electrode with respect to the blue light-emitting layer.

13. The display device according to claim 1,
wherein the red light-emitting layer, the green light-emitting layer, and the blue light-emitting layer are layered in this order, and
the red light-emitting layer and the green light-emitting layer overlap each other in the plan view.

14. The display device according to claim 13, further comprising:
a common electrode having first polarity and being electrically connected to all of the red light-emitting layer, the green light-emitting layer, and the blue light-emitting layer;
a first electrode having second polarity opposite to the first polarity and being electrically connected to the red light-emitting layer;
a second electrode having the second polarity and being electrically connected to the green light-emitting layer; and
a third electrode having the second polarity and being electrically connected to the blue light-emitting layer,
wherein the common electrode includes a third common electrode, a fourth common electrode, and a fifth common electrode being electrically connected to each other, and
the first electrode, the red light-emitting layer, the third common electrode, the second electrode, the green light-emitting layer, the fourth common electrode, the third electrode, the blue light-emitting layer, and the fifth common electrode are layered in this order.

15. The display device according to claim 1, further comprising:
a common electrode having first polarity and being electrically connected to all of the red light-emitting layer, the green light-emitting layer, and the blue light-emitting layer;
a first electrode having second polarity opposite to the first polarity and being electrically connected to the red light-emitting layer;
a second electrode having the second polarity and being electrically connected to the green light-emitting layer; and
a third electrode having the second polarity and being electrically connected to the blue light-emitting layer,
wherein the common electrode and the first to third electrodes are formed of a transparent material.

16. The display device according to claim 1, further comprising:
a substrate on which the red light-emitting layer, the green light-emitting layer, and the blue light-emitting layer are mounted,
wherein the red light-emitting layer and the green light-emitting layer include a quantum dot, and are disposed on the substrate side with respect to the blue light-emitting layer, and
display is performed on an opposite side to the substrate with respect to the blue light-emitting layer.

17. (canceled)

18. A method for manufacturing a display device, the method comprising:
forming, on a substrate, a first electrode to be electrically connected to a red light-emitting layer;
forming, on the substrate, a second electrode to be electrically connected to a green light-emitting layer;
forming the red light-emitting layer on the first electrode;
forming the green light-emitting layer on the second electrode;
forming, on the red light-emitting layer and the green light-emitting layer, a first common electrode portion common to the red light-emitting layer and the green light-emitting layer;
forming, on the first common electrode portion, a third electrode to be electrically connected to a blue light-emitting layer;
forming the blue light-emitting layer on the third electrode; and
forming a second common electrode portion to be electrically connected to the blue light-emitting layer,
wherein a light-emitting area of the blue light-emitting layer is greater than a light-emitting area of the red light-emitting layer, and the light-emitting area of the red light-emitting layer is greater than a light-emitting area of the green light-emitting layer.

19. A method for manufacturing a display device, the method comprising:
forming, on a substrate, a first electrode to be electrically connected to a red light-emitting layer;
forming the red light-emitting layer on the first electrode;
forming a third common electrode portion on the red light-emitting layer;
forming, on the third common electrode portion, a second electrode to be electrically connected to a green light-emitting layer;
forming the green light-emitting layer on the second electrode;
forming a fourth common electrode portion on the green light-emitting layer;
forming, on the fourth common electrode portion, a third electrode to be electrically connected to a blue light-emitting layer;
forming the blue light-emitting layer on the third electrode; and
forming a fifth common electrode portion on the blue light-emitting layer,
wherein a light-emitting area of the blue light-emitting layer is greater than a light-emitting area of the red light-emitting layer, and the light-emitting area of the red light-emitting layer is greater than a light-emitting area of the green light-emitting layer.
